(19) United States
(12) Patent Application Publication
(10) Pub. No.: US 2012/0280341 A1
(43) Pub. Date: Nov. 8, 2012

(54) INTEGRATED PASSIVE COMPONENT

(76) Inventor: Joerg FRANKE, Freiburg (DE)

(21) Appl. No.: 13/464,304

(22) Filed: May 4, 2012

(30) Foreign Application Priority Data
May 4, 2011 (DE) DE 102011100487.8

(51) Int. Cl. H01L 29/82

(52) U.S. Cl. 257/427; 257/E29.323

(57) ABSTRACT

An integrated passive component having a semiconductor body, arranged on a metal substrate and having a first surface, and a plurality of metal surfaces formed on the surface, a passivation layer formed on the surface, an integrated circuit formed near the surface of the semiconductor body, whereby the integrated circuit is connected to metal surfaces via traces formed below the passivation layer, a part of the metal surfaces is connected to pins via bonding wires, a first part of a first coil, the part formed in part above the semiconductor body, whereby the first coil with a plurality of turns has a longitudinal axis formed substantially parallel to the surface of the semiconductor body, and a second part of the first coil is formed below the semiconductor body.

This nonprovisional application claims priority under 35 U.S.C. §119(a) to German Patent Application No. DE 10 2011 100 487.8, which was filed in Germany on May 4, 2011, and which is herein incorporated by reference.

### BACKGROUND OF THE INVENTION

1. Field of the Invention

The invention relates to an integrated passive component.

2. Description of the Background Art

DE 600 32 336 T2, DE 699 37 868 T2 (which corresponds to U.S. Pat. No. 6,410,974), and DE 10 2008 050 972 A1 (which corresponds to U.S. Pat. No. 7,834,464) disclose different approaches for integrating a coil on or with or in a semiconductor body. Thus, for example, the formation of a spiral inductor in the different trace layers under the passivation of the semiconductor body is known from the disclosure in DE 600 32 336 T2.

### SUMMARY OF THE INVENTION

It is therefore an object of the invention to provide a device that refines the state of the art. The object is attained in an embodiment by an integrated passive component having a semiconductor body, arranged on a metal substrate and having a first surface, and a plurality of metal surfaces formed on the surface, a passivation layer formed on the surface, an integrated circuit formed near the surface of the semiconductor body, whereby the integrated circuit is connected to metal surfaces by means of traces formed below the passivation layer, a part of the metal surfaces is connected to pins by means of bonding wires, a first part of a first coil, the part formed in part above the semiconductor body, whereby the first coil with a plurality of turns has a longitudinal axis formed substantially parallel to the surface of the semiconductor body, and a second part of the first coil is formed below the semiconductor body.

An advantage of the integrated passive component of the invention is that a component formed as a first coil and having a plurality of turns can be integrated into a standard semiconductor fabrication process. It should be noted that preferably each turn of the first coil has a first section of wire and a second section, which is formed as a part of the metal substrate, also called a lead frame. As a result, at least one part or the entire semiconductor body lies within the first coil. Tests by the applicant have shown that according to the device of the invention coils with a high rating, preferably a rating above 5, most preferably with a rating above 10, can be integrated cost-effectively and reliably into a semiconductor housing.

After the fabrication of the integrated circuit, whereby a metal process, which is generally carried out repeatedly to form a plurality of trace layers, is included in the fabrication process, after the formation of the topmost trace layer a passivation layer, formed preferably as a dielectric layer, is produced. In this case, in a so-called pad window etching process, the metal surfaces, which are connected to the traces and which preferably are formed in the topmost metal layer and are called pads, are etched free. Next, the wafers, which has a plurality of semiconductor bodies, which are also called dies, are diced. After this, the dies or the individual semiconductor bodies are arranged on a metal substrate, also called a lead frame. The first part of the first coil, i.e., those parts of the turns of the first coil that are arranged in part above the semiconductor body and are preferably made from a bonding wire, can be produced in a subsequent bonding process.

In an embodiment, in the bonding process the first part of the turn of the first coil, the first part being above the semiconductor body, is connected by means of a bond to the second part of the turn of the first coil, the second part formed below the semiconductor body as a pin; i.e., the wire parts of the respective turn are connected to individual preferably strip-shaped sections of the metal substrate, the so-called pins. It is preferred that the first part of the first coil surrounds the semiconductor body on two side surfaces. According to an alternative embodiment, parts of the lead frames, i.e., the pins of the metal substrate, can be raised, for example, by means of a die. As a result, the side surfaces of the semiconductor body are not surrounded or surrounded only partially by the first part of the first coil.

According to an embodiment, to increase the stability of the structure, particularly in a strip-shaped design of the lead frame, below the semiconductor body a plate can be inserted force-fittingly between the semiconductor body and the metal substrate. The plate is made of an electrically insulating material and preferably connects the strip-shaped lead frame parts of the metal substrate.

Furthermore, in the bonding process metal surfaces can also be wired with pins, which inter alia are used for electrical contacting of the integrated circuit. It is understood that a part or all connections of the coil, for example, also an optional center tap of the coil, can be connected to pins. As a result, the coil in a housed state can also be contacted from the outside and supplied with external signals.

In an embodiment, all or part of the connections of the first coil can be connected to the integrated circuit. As a result, particularly coils for resonant circuits can be completely integrated; i.e., outer pins for connecting an external coil are superfluous.

It is furthermore preferred to arrange in the surface, preferably below the passivation layer of the semiconductor body, a magnetic field sensor, which can be formed preferably as a Hall sensor. Because the semiconductor body is formed in the interior of the coil, the field lines run virtually parallel to the semiconductor surface.

According to an embodiment, it is possible to form a second coil within the first coil and in this way to achieve a transformer coupling between both coils. It is preferred to make the second coil in such a way that the first sections of turns of the second coil are formed as traces. Further, it is preferred that second sections of a turn of the second coil are formed from wire, particularly bonding wires, whereby the ends of the second sections are contacted on a metal surface on the surface of the semiconductor body by means of a bond.

As the fabrication of the first coil and of the second coil as well can be readily integrated cost-effectively into the fabrication process, it is preferred to arrange both the individual coils or the two coils and the semiconductor body in a single mutual housing. In this regard, the housing, which preferably is formed of plastic, is produced in a so-called molding process. For example, a QFN housing with an integrated coil can be formed.

In an embodiment, the integrated passive component can be used for magnetic field-free position measurement. In this regard, the change in inductance in the first coil or second coil, because of an approach of the component to a magnetic material, is determined as a measure of the distance. Because the measured change in inductance is compared with values from a predetermined value field, in a known arrangement the distance of the component to the magnetic material can be determined.

In another embodiment, the passive component can be used for calibrating and testing magnetic field sensors. To this end, a current is applied to the coil above of the magnetic field sensor. In this regard, both the current can be adjusted in such a way that an outer magnetic field is shielded and thereby the magnetic field sensor is virtually or completely magnetic field-free, and in an alternative application a magnetic field with a defined strength is generated so that, for example, in the case of the Hall sensor a specific Hall voltage is present.

In an embodiment, the component is used for transmitting data from a coil to a magnetic field sensor. In this case, data can be transmitted in the form of an optocoupler in a galvanically decoupled manner by means of a preferably changing magnetic field.

In another application, the dynamic measuring range can be increased by means of the combination of coil and magnetic field sensor. In comparison to magnetic fields designed thus far only for magnetic field sensors and, accordingly, slowly over time changing magnetic fields, now in addition the strength of rapidly changing magnetic fields can be determined by means of the induction in the coil as well.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a schematic cross-sectional view of a first embodiment;

FIG. 2 is a perspective view of the embodiment of FIG. 1;

FIG. 3 is a schematic plan view of an embodiment of an integrated coil; and

FIG. 4 is a schematic plan view of an embodiment of two nested coils and an integrated circuit.

### DETAILED DESCRIPTION

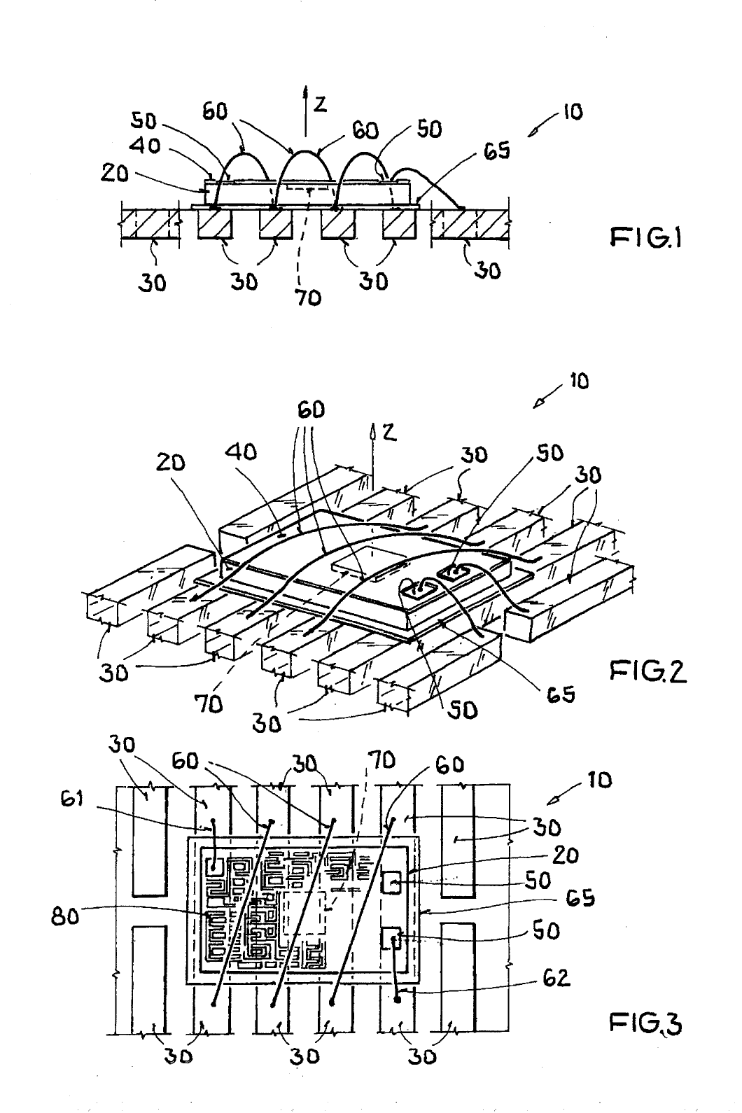

The illustration in FIG. 1 shows an embodiment of an integrated passive component 10, having a semiconductor body 20 on a metal substrate 30. Metal substrate 30 has at least partially individual metal strips, so-called pins. Semiconductor body 20 has on the surface openings in passivation layer 40. Passivation layer 40 has a nitride layer. Metal surfaces 50 are formed in the openings of passivation layer 40. A part of metal surfaces 50 can be formed near the edge of semiconductor body 20. A first part of a first coil, having a plurality of turns, is formed above the surface and on two opposite side surfaces of semiconductor body 20.

A second part of the first coil is formed below semiconductor body 20. The longitudinal axis of the first coil is substantially parallel to the surface of semiconductor body 20. The turns in the first part of the first coil have sections of wires 60, preferably bonding wires. Wire 60 has two ends, each of which are connected to the pins with a bond. The wires are connected to the pins by a standard bonding process. Accordingly, a turn of the first coil in each case has a section of metal substrate 30, i.e., pin, and a section of wire 60. It should be noted that metal substrate 30 is formed in the shape of a strip below semiconductor body 20. As a result, the individual coil turns are insulated from one another. According to an alternative embodiment, to increase the stability of the structure a plate 65 is inserted force-fittingly between semiconductor body 20 and metal substrate 30. Plate 65 is made from an electrically insulating material.

Semiconductor body 20 is arranged substantially within the coil. A magnetic field sensor 70 is integrated in the surface of semiconductor body 20. The strength of the magnetic field within the first coil can be determined very precisely by magnetic field sensor 70, which is formed preferably as a Hall sensor. The current strength in the coil can be determined from the strength of the magnetic field. It should be noted, however, that magnetic field sensor 70 is superfluous provided that the first coil is used as part of a resonant circuit, for example, within the scope of an integrated circuit.

A plan view of the embodiment of FIG. 1 is shown in FIG. 2. Only the differences in regard to the illustration in FIG. 1 will be explained below. For reasons of illustration, passivation layer 40 is not shown. The upper part of the first coil is formed from sections of wires 60. The lower part of the first coil is formed from metal strips, the pins of the lead frame. The individual wires 60 each end on the pins. Turns of the first coil are connected in an alternating manner to a wire 60 or a pin. In an embodiment which is not shown, to make the sections of the wires short, the immediately opposite pins of the first coil are connected by means of wires 60, whereas the metal strips have an uncoiled profile below semiconductor body 20. Metal surfaces 50 are connected to pins by means of a bonding wire on the right outer end.

Another embodiment is shown in a plan view in FIG. 3. Only the differences in regard to the embodiment of FIG. 2 will be explained below. In the present case, the coil is connected by means of a first connecting wire 61 and a second connecting wire 62 each to a metal surface 50. Metal surfaces 50 are connected in turn to traces 80, which are part of an integrated circuit. The first coil can be used inter alia as a resonant circuit coil.

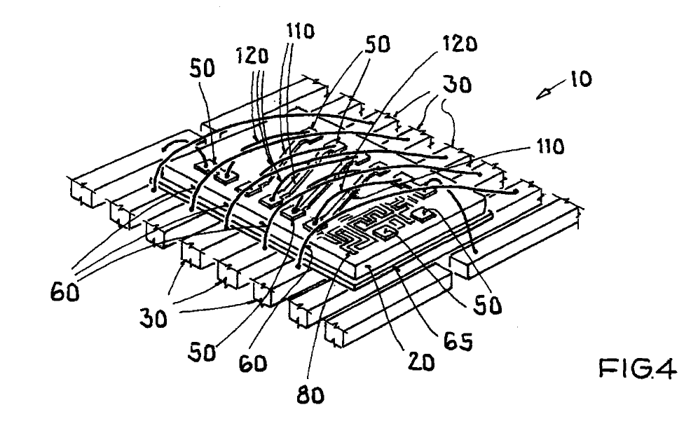

A schematic plan view of an embodiment with a second coil, formed in the first coil, and an integrated circuit are shown in the illustration of FIG. 4. Only the differences in regard to the embodiment of FIG. 3 will be explained below. The second coil comprises a plurality of turns and is formed on the surface and above the surface of semiconductor body 20. The longitudinal axis of the second coil is substantially parallel to the surface of semiconductor body 20 and parallel to the longitudinal axis of the first coil. The second coil has a lower part, which runs in the surface of semiconductor body 20, and an upper part. The lower part is formed as a trace 110 below passivation layer 40, whereas the upper part of the first coil is formed of sections of wires 120, preferably bonding wires, above passivation layer 40. As a result, a turn of the second coil has, in each case, a section of a trace 110, which is connected at both ends to a metal surface 50, and a section of a wire 120. Wire 120 has two ends, each of which is connected to metal surface 50 by means of a bond.

According to the design of the first coil and/or the second coil and the connection of the other metal surfaces by means of bonding to the pins (not shown), in a subsequent molding process the semiconductor can be integrated together with the first coil and/or with the second coil in the same housing (not shown).

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An integrated passive component comprising:
a semiconductor body arranged on a metal substrate and having a first surface and a plurality of metal surfaces formed on the first surface, a portion of the metal surfaces being connectable to pins via bonding wires;
a passivation layer formed on the first surface;
an integrated circuit formed near the surface of the semiconductor body, the integrated circuit being connected to the metal surfaces via traces formed below the passivation layer; and
a first part of a first coil, the first part being formed above the semiconductor body, the first coil having a plurality of turns having a longitudinal axis formed substantially parallel to the surface of the semiconductor body and a second part of the first coil being formed below the semiconductor body.

2. The integrated passive component according to claim 1, wherein at least one part of the turns of the second part of the first coil is formed as pins of the metal substrate and wherein the pins are arranged at least partially below the semiconductor body.

3. The integrated passive component according to claim 1, wherein the first part of the first coil surrounds the semiconductor body on two side surfaces.

4. The integrated passive component according to a claim 1, wherein in the first part of the first coil at least one part of the turns is formed from a wire, preferably a bonding wire.

5. The integrated passive component according to claim 1, wherein the part of the turn of the first coil, the part formed above the semiconductor body is connectable via a bond to the part of the turn of the first coil, the part formed below the semiconductor body.

6. The integrated passive component according to claim 1, wherein the coil is connectable the integrated circuit.

7. The integrated passive component according to claim 1, wherein a magnetic field sensor is formed in the first surface of the semiconductor body.

8. The integrated passive component according to claim 7, wherein the magnetic field sensor is formed as a Hall sensor.

9. The integrated passive component according to claim 1, wherein the semiconductor body and the first coil are arranged in a single housing.

10. The integrated passive component according to claim 1, wherein a second coil is provided within the first coil.

11. The integrated passive component according to claim 12, wherein the housing is formed plastic.

12. The integrated passive component according to claim 1, wherein the integrated passive component is a component for magnetic field-free position measuring.

13. The integrated passive component according to claim 12, wherein the integrated passive component is configured for measuring magnetic fields.

14. The integrated passive component according to claim 12, wherein the integrated passive component is configured for calibrating and testing magnetic field sensors.

15. The integrated passive component according to claim 12, wherein the integrated passive component is configured for transmitting data to a magnetic field sensor.
